(19) United States
(12) Patent Application Publication
(10) Pub. No.: US 2026/0096401 A1
(43) Pub. Date: Apr. 2, 2026

(54) MASK MODIFICATION METHOD

(71) Applicant: Tokyo Electron Limited, Tokyo (JP)

(72) Inventor: Minjoon Park, Albany, NY (US)

(21) Appl. No.: 18/904,348

(22) Filed: Oct. 2, 2024

(51) Int. Cl. H01L 21/033; C23C 14/54; H01L 21/311; H01L 21/768

(52) U.S. Cl. CPC H10P 76/4083; C23C 14/54; H10P 50/73; H10P 76/405; H10W 20/089

(57) ABSTRACT

A method for processing a substrate includes receiving the substrate on a substrate holder, the substrate including a patterned mask disposed over a patterned underlying layer, the patterned mask including notches. The method further includes having a plurality of polar angles and a plurality of processing times, each of the plurality of polar angles having an associated one of the plurality of processing times, and processing the substrate with a cyclic process for each of the plurality of polar angles. Each cycle of the cyclic process includes selecting a polar angle (θᵢ) from the plurality of polar angles. Each cycle further includes tilting a processing tool such that a beam emitted from the processing tool strikes the substrate at the selected polar angle (θᵢ), and emitting the beam at the selected polar angle (θᵢ) for an i^{th} timeframe (tᵢ) corresponding to the selected polar angle (θᵢ) to deposit an i^{th} layer over the notches.

### TECHNICAL FIELD

The present invention relates generally to the field of semiconductor manufacturing processes, and, in particular embodiments, to a system and method for mask modification by controlling mask shapes during high aspect ratio contact (HARC) and high aspect ratio trench (HART) etching processes.

### BACKGROUND

In the field of semiconductor manufacturing, high aspect ratio contact (HARC) and high aspect ratio trench (HART) etching processes are crucial for creating increasingly miniaturized and densely packed electronic components. As the aspect ratio of features increases, maintaining precise control over the etching process becomes more challenging. Traditional approaches to reducing bowing often involve strengthening polymer passivation during the etching process. However, these methods can lead to trade-offs with other parameters, such as increased clogging, reduced top-to-bottom critical dimension (CD) ratio, and contact deformation.

### SUMMARY

In accordance with an embodiment of this disclosure, a method for processing a substrate includes receiving the substrate on a substrate holder, the substrate including a patterned mask disposed over a patterned underlying layer, the patterned mask including notches. The method further includes having a plurality of polar angles and a plurality of processing times, each of the plurality of polar angles having an associated one of the plurality of processing times, and processing the substrate with a cyclic process for each of the plurality of polar angles. Each cycle of the cyclic process includes selecting a polar angle (θᵢ) from the plurality of polar angles, the selected polar angle being higher than any polar angle from the plurality of polar angles previously selected in the cyclic process for processing the substrate and lower than any polar angle from the plurality of polar angles remaining to be selected in the cyclic process for processing the substrate. Each cycle of the cyclic process further includes tilting a processing tool such that a beam emitted from the processing tool strikes the substrate at the selected polar angle (θᵢ), and emitting the beam at the selected polar angle (θᵢ) for an i^{th} timeframe (tᵢ) corresponding to the selected polar angle (θᵢ) to deposit an i^{th} layer over the notches.

In accordance with another embodiment of this disclosure, a method for shaping a patterned mask on a substrate includes receiving the substrate on a substrate holder, the substrate including the patterned mask disposed over an underlying layer, the patterned mask including a feature pattern. The method further includes determining a topological map of the patterned mask using a light detector, and depositing i layers over the patterned mask to reshape the patterned mask, each of the i layers deposited by a processing tool directed over the substrate at a corresponding i^{th} polar angle (θᵢ) for a corresponding i^{th} timeframe (tᵢ), where i is a positive integer between 1 and 100 determined using the topological map of the patterned mask and a desired shape for the feature pattern.

And in accordance with yet another embodiment of this disclosure, a system for processing a substrate includes a substrate holder disposed in a processing chamber, a processing tool, a light detector, and a controller coupled to the substrate holder, the processing tool, the light detector, and a memory storing instructions to be executed by the controller. The instructions, when executed, cause the controller to receive the substrate on the substrate holder, the substrate including a patterned mask disposed over an underlying layer, the patterned mask including a feature pattern, and determine a topological map of the patterned mask using the light detector. And the instructions, when executed further, cause the controller to deposit i layers over the patterned mask to reshape the patterned mask and form a modified patterned mask including a reshaped feature pattern, each of the i layers deposited by the processing tool directed over the substrate at a corresponding i^{th} polar angle (θᵢ) for a corresponding i^{th} timeframe (tᵢ), where i is a positive integer between 1 and 100 determined using the topological map of the patterned mask and a desired shape for the feature pattern.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a cross-sectional view of a substrate illustrating various steps of a mask modification method in accordance with an embodiment of this disclosure;

FIG. 2 is a cross-sectional view of a substrate illustrating further steps of the mask modification method in accordance with an embodiment of this disclosure;

FIGS. 3A-3D are cross-sectional views of a substrate throughout various steps of a processing method incorporating the mask modification method of FIGS. 1-2 in accordance with an embodiment of this disclosure;

FIGS. 4A-4B are schematic diagrams used to illustrate polar and azimuthal angles of a flux or beam impacting a substrate in accordance with an embodiment of this disclosure;

FIGS. 5A-5B are cross-sectional view schematic diagrams of a substrate comprising a notched mask in accordance with an embodiment of this disclosure;

FIG. 6 is a schematic diagram of a processing system which may implement the mask modification method in accordance with an embodiment of this disclosure;

FIG. 7 is a flowchart of a mask modification method in accordance with an embodiment of this disclosure; and

FIG. 8 is a flowchart of a mask modification method in accordance with an embodiment of this disclosure.

### DETAILED DESCRIPTION OF ILLUSTRATIVE EMBODIMENTS

In the realm of high aspect ratio contact (HARC) and high aspect ratio trench (HART) etching, maintaining precise control over the etching process becomes increasingly challenging as feature sizes continue to shrink. One challenge is the formation of bowing in the etched structures, which can compromise the integrity and performance of the final device. Bowing can occur when ions scatter from a mask notch (or facet) and strike sidewalls of the contact or trench being etched. Traditional approaches to mitigate this issue often involve strengthening polymer passivation during the etching process. However, these methods frequently lead to undesirable trade-offs, such as increased clogging, reduced top-to-bottom critical dimension (CD) ratio, and contact deformation. Furthermore, the use of new materials like metal hardmasks, while offering higher selectivity, can exacerbate the mask notch (or mask facet) challenge.

In various embodiments, a method for controlling mask notch shape during high aspect ratio contact (HARC) and high aspect ratio trench (HART) etching processes is provided. This method utilizes oblique angle deposition (OAD) techniques to reshape the mask notch, effectively reducing bowing without significantly impacting other processing parameters. In one or more embodiments, the OAD process is implemented using a physical vapor deposition (PVD) system, or a gas cluster beam (GCB) system which may emit a particle beam, e.g., comprising gas clusters. The method involves depositing material onto the notched mask at carefully controlled angles and positions, gradually reshaping the notched mask into a squarer shape (or other desired shapes according to a processing recipe). This approach provides an additional control knob for the etching process, allowing for bowing reduction without the traditional trade-offs associated with strengthening polymer passivation. In an embodiment, the method can be particularly beneficial when using metal hardmasks, which typically offer higher selectivity but are prone to mask notch issues due to higher sputtering yield of metals than carbon. By minimizing the downside of metal hardmasks, this technique may enable the use of thinner masks while maintaining or improving etch performance. The ability to precisely control the mask notch shape addresses the challenges of narrowing process windows and the difficulty of balancing multiple process parameters in high aspect ratio etching processes.

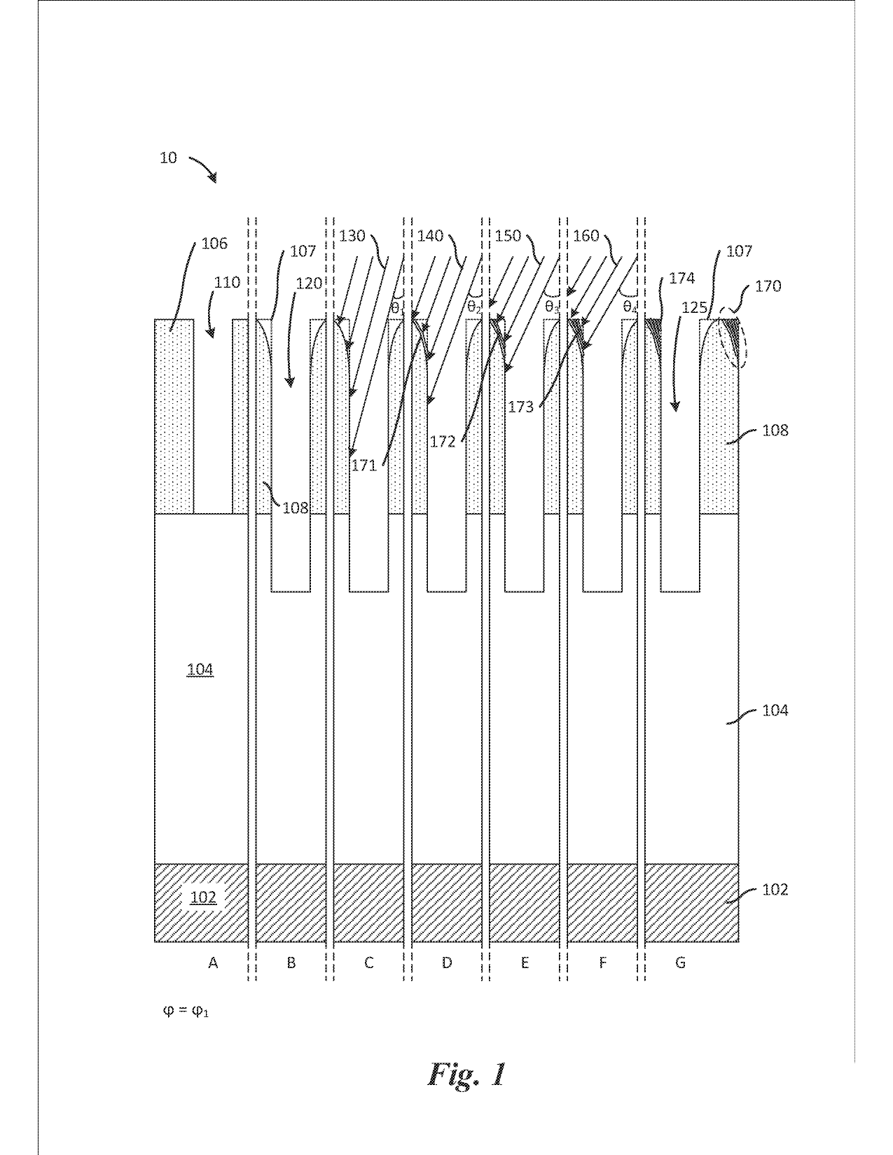

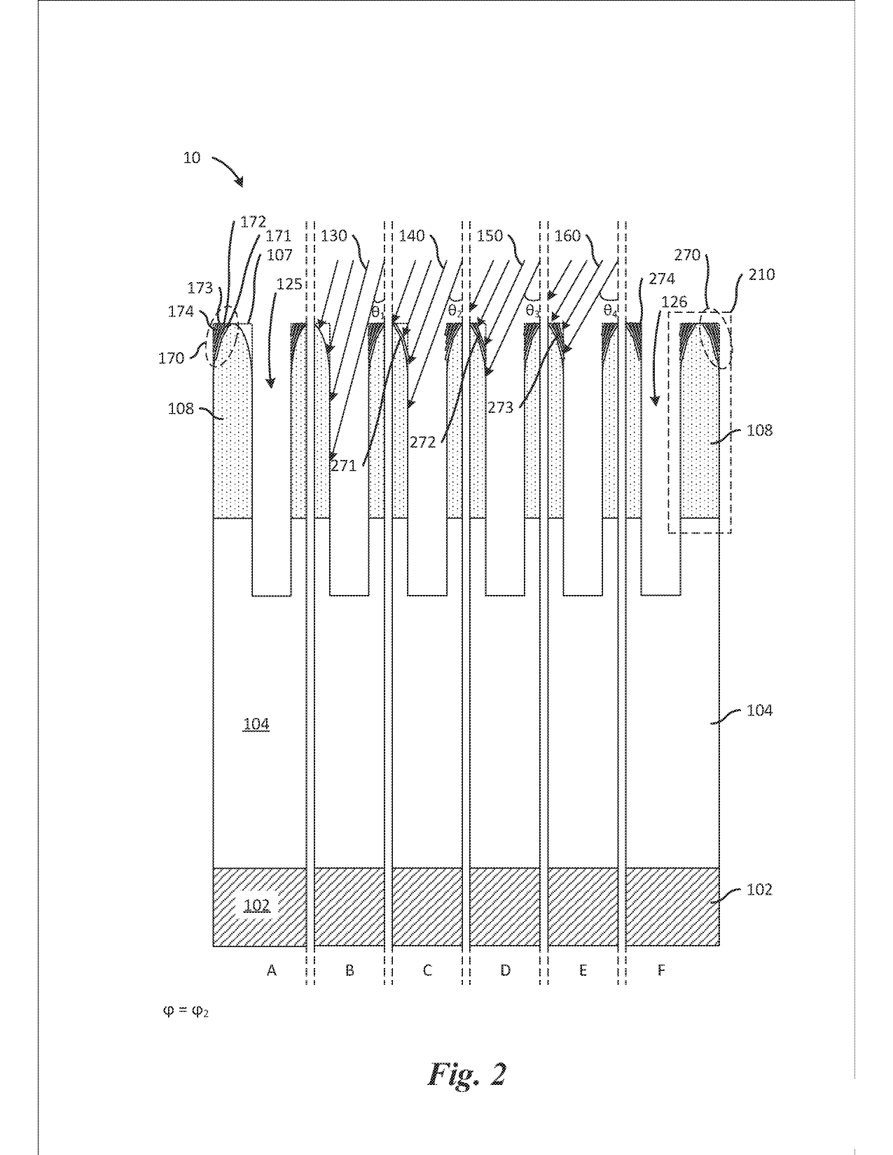

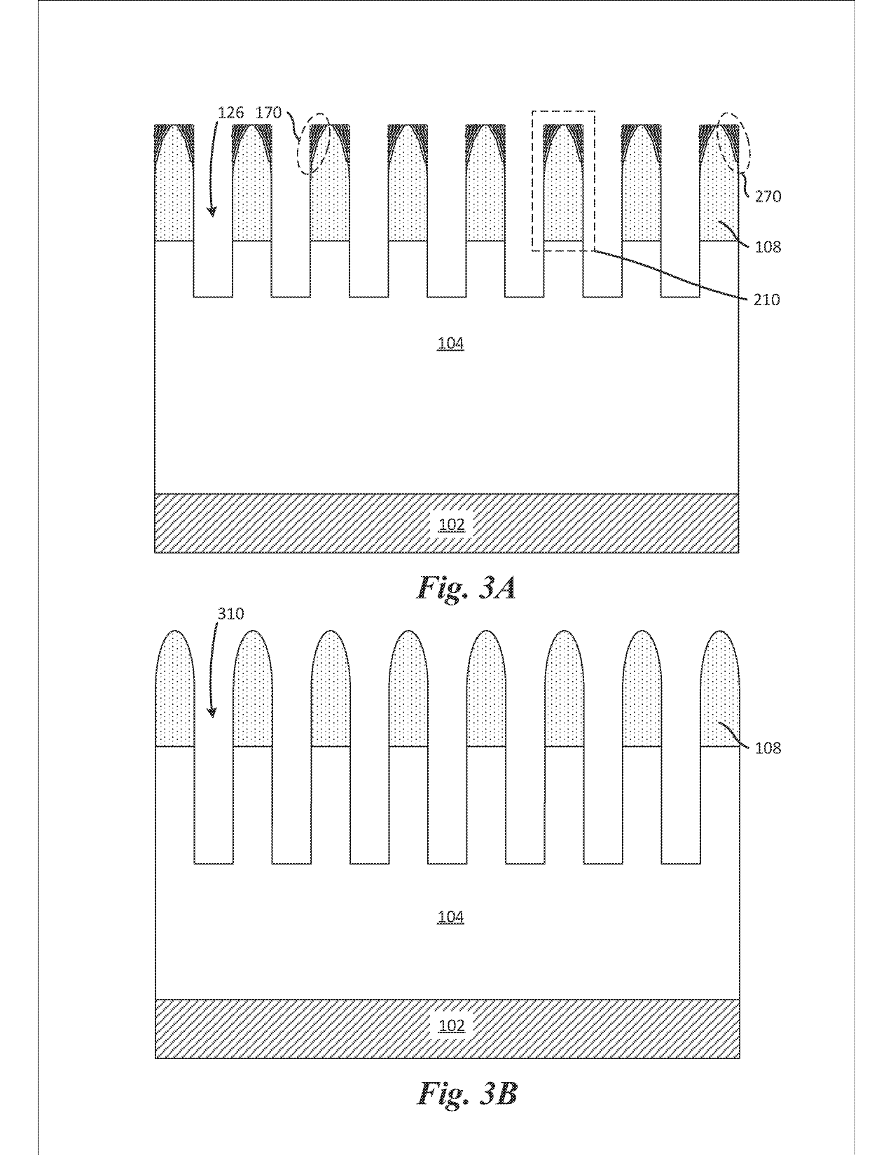

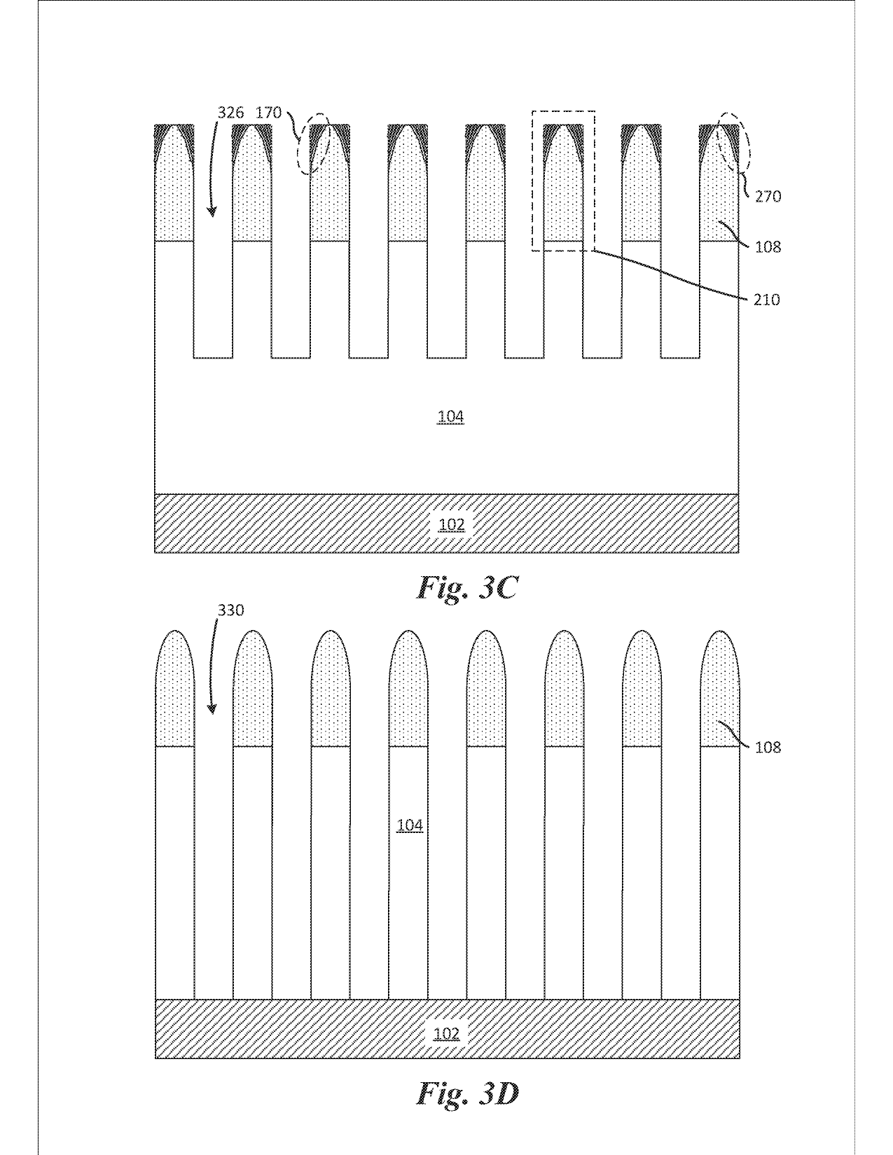

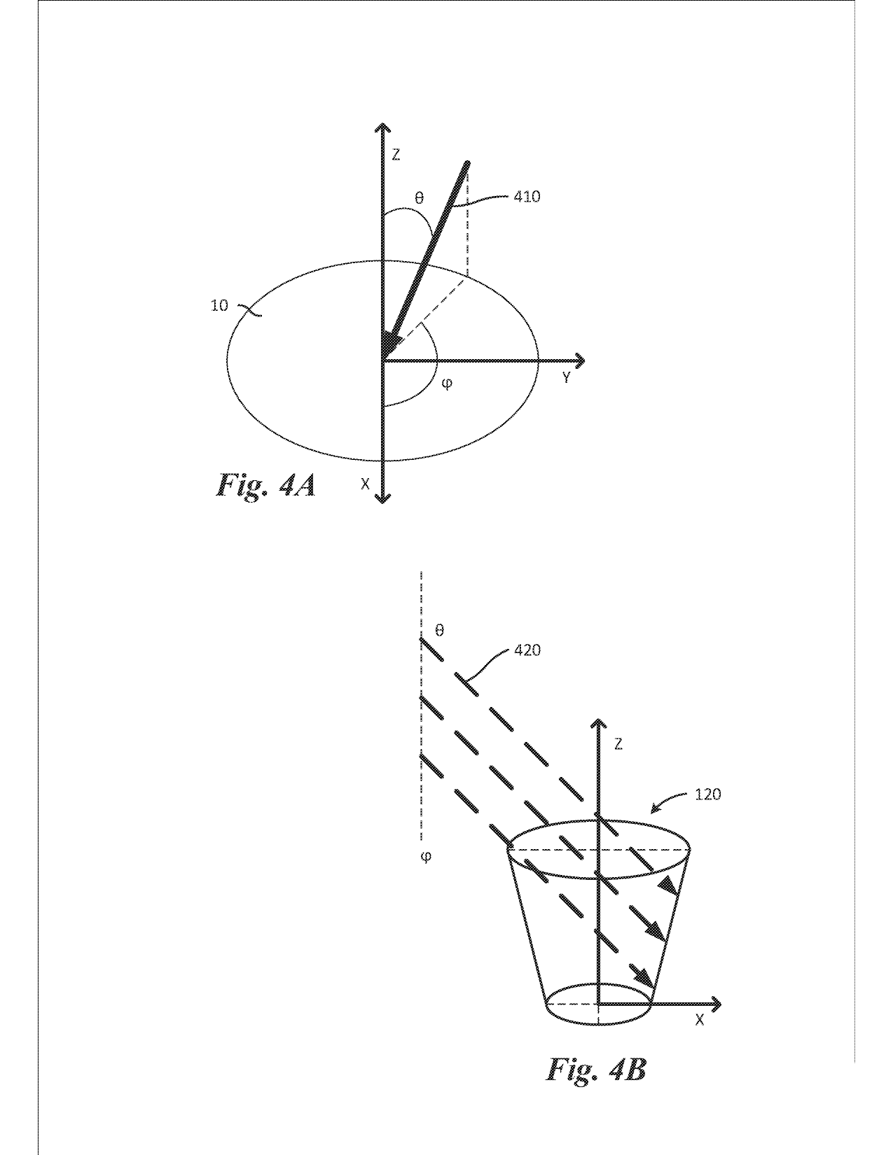

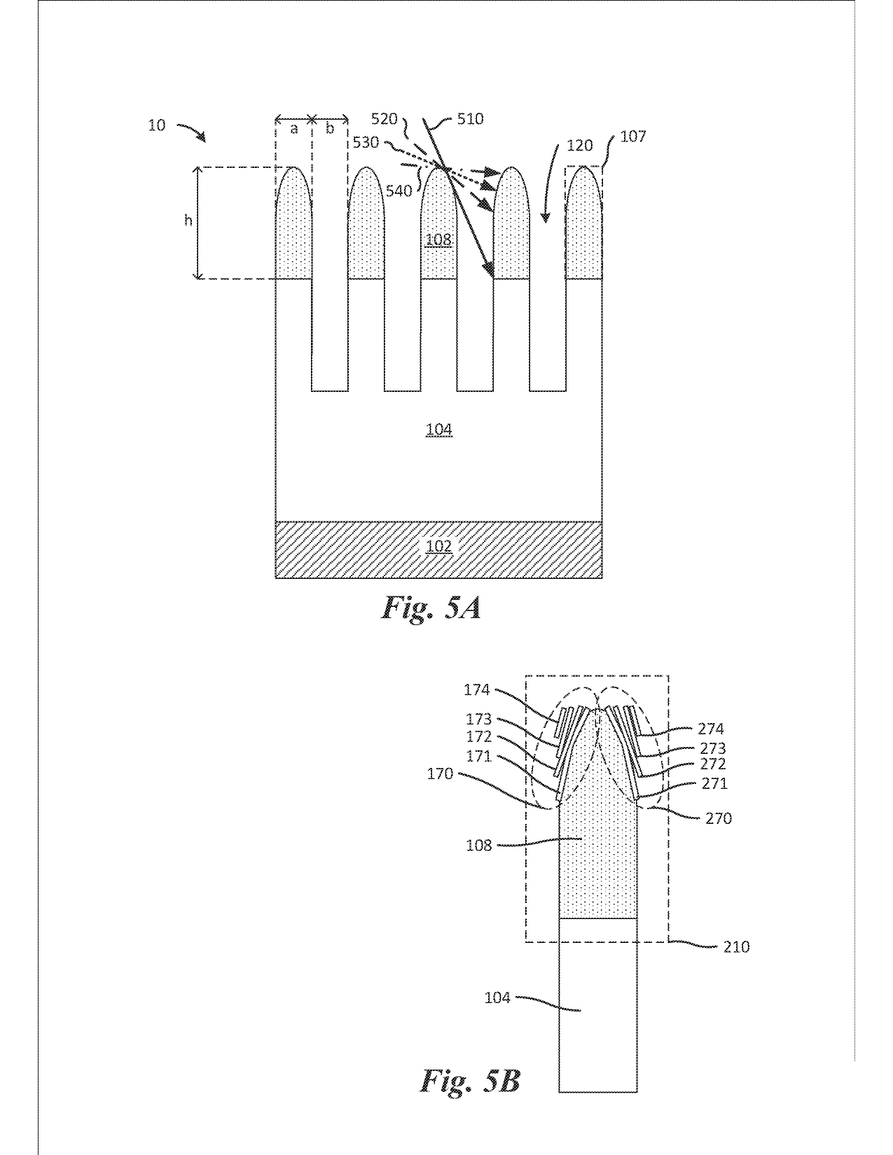

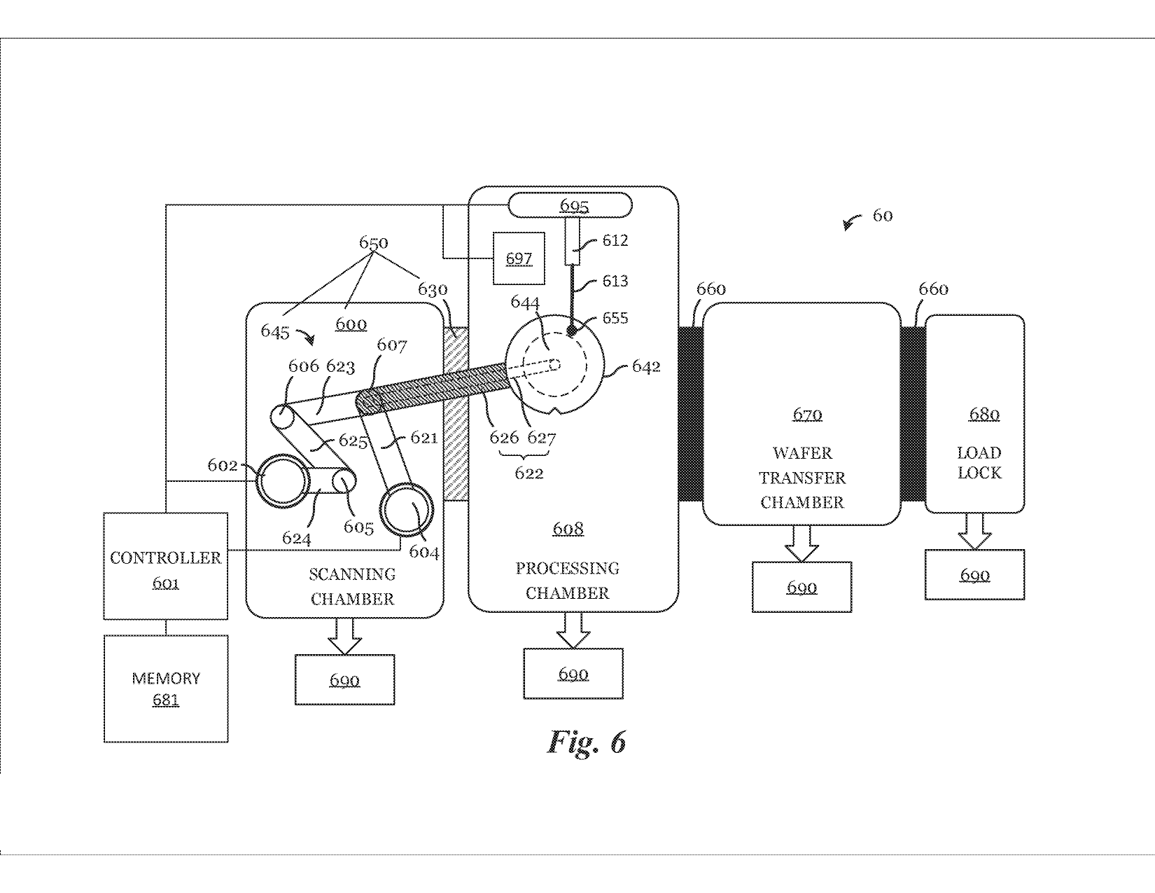

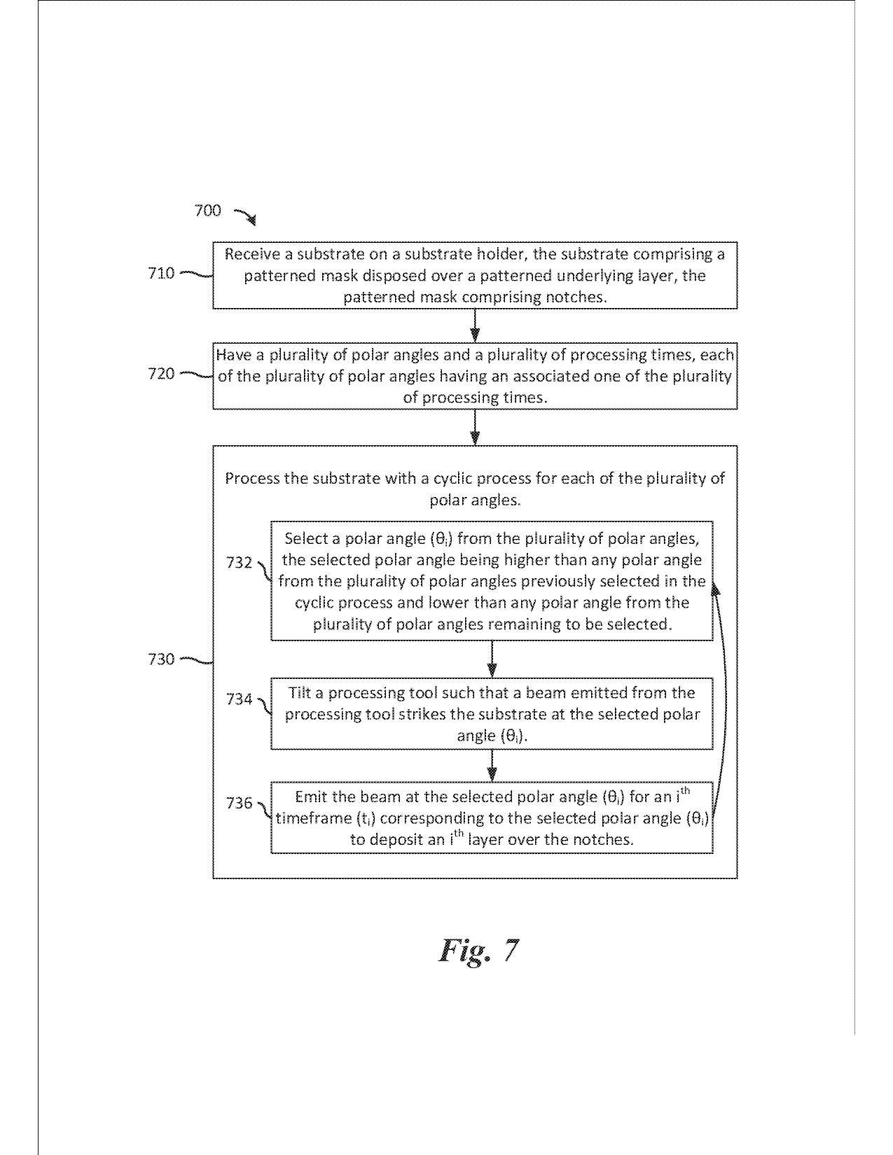

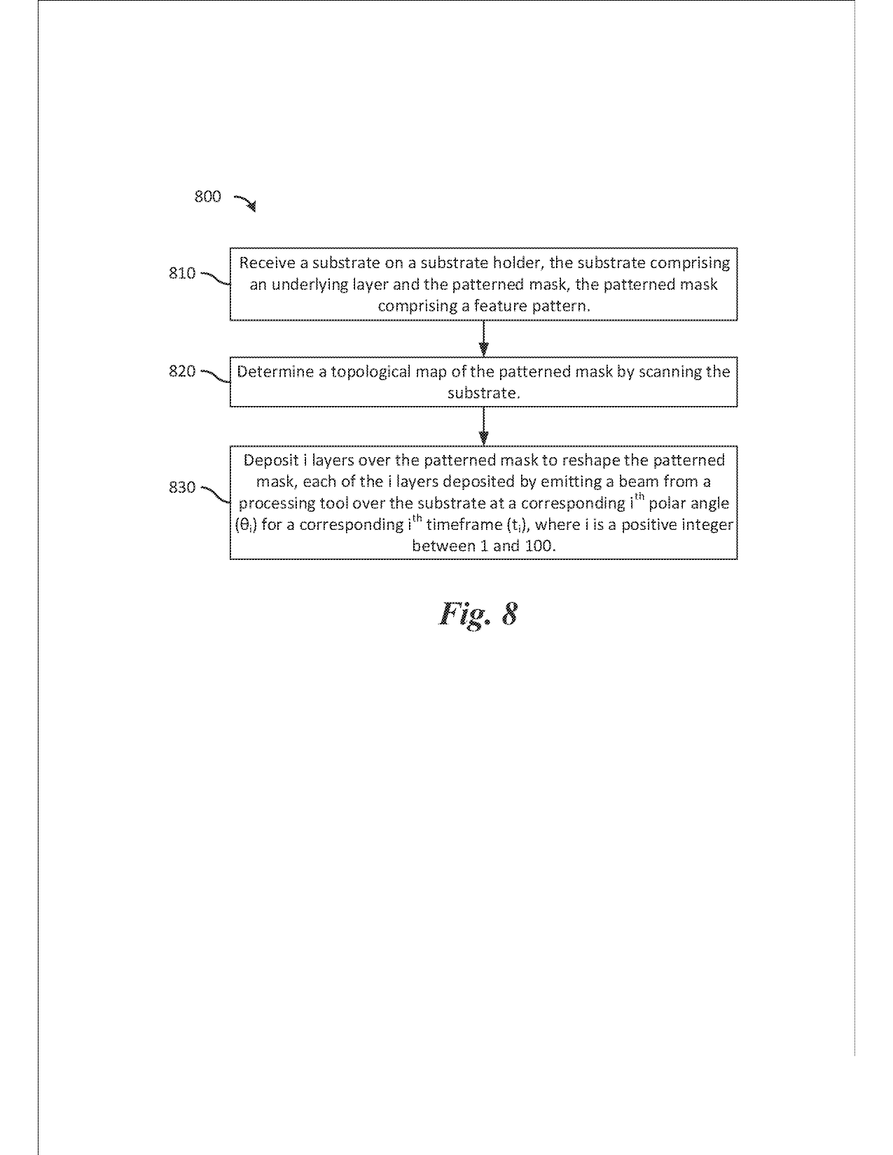

Embodiments provided below describe various methods, apparatuses and systems for processing a substrate, and in particular, to methods, apparatuses, and systems for repairing a notched mask (or faceted mask) by depositing various layers at varying oblique angles over the substrate. The following description describes the embodiments. FIG. 1 is used to describe various steps of a mask modification method which may be used to prevent bowing in high-aspect-ratio features being formed. FIG. 2 illustrates additional steps of the mask modification method which may be implemented after the steps described using FIG. 1. Various etching, and mask modification cycles, which may be used to form high-aspect-ratio (HAR) features in the substrate without bowing are described using the cross-sectional views of the substrate in FIGS. 3A-3D. A spherical coordinate system which may be used to describe the polar angle and azimuthal angle of a processing beam or flux used in the deposition of the various layers to repair the notched mask of the substrate is described using FIGS. 4A-4B. FIGS. 5A-5B are cross-sectional views of the substrate comprising a notched mask used to described how the various polar angles and azimuthal angles used for the various layers being deposited are determined. FIG. 6 is a schematic diagram of a processing system which may be used to implement the mask modification method of this disclosure. And FIGS. 7-8 are flowcharts used to describe two embodiment methods of the mask modification method.

FIG. 1 illustrates a cross-sectional view of a substrate 10 through various steps of a mask modification method. In various embodiments, this method restores a notched mask by using various deposition beams or fluxes at a plurality of different polar angles to deposit various layers over the notched mask, and thereby restore (or reshape) the mask as desired. The substrate 10 is illustrated through various time steps (A-G) of the mask modification method of this disclosure, where each step is separated by the vertical dashed lines, and each step is labeled at the bottom of the substrate 10.

Step A of FIG. 1 illustrates the initial state of the substrate 10 after patterning the mask layer 106 to form a patterned mask comprising a feature pattern, which may be transferred into a target layer 104 disposed beneath the mask layer 106. In those embodiments, the mask layer 106 is a patterned mask. The substrate 10 comprises an underlying layer 102 and the target layer 104 above the underlying layer 102 and the mask layer 106 over the target layer 104. The mask layer 106 is formed on top of the target layer 104 and patterned to define openings 110 for subsequent etching processes. In various embodiment, the openings 110 may be a feature pattern for forming high-aspect-ratio contacts (HARCs) or for forming high-aspect-ratio trenches (HARTs).

Step B illustrates the substrate 10 after an initial etching process. In one or more embodiments, this etching process begins to form a feature, such as a trench or contact, in the target layer 104. The etching process is halted before significant bowing occurs due to the formation of a notch in the mask layer 106, resulting in the notched mask 108. A former shape 107 of the mask layer 106 is illustrated as a dashed box around the notch in the notched mask 108. Additionally, the initial etching process begins to transfer the feature pattern of the patterned mask layer 106 to the target layer 104, and subsequently forms a notched opening 120.

Steps C through F depict the sequential deposition of multiple layers to restore the former shape 107 of the notched mask 108. In various embodiments, this restoration process involves the deposition of first restoration layers 170 on one side of the notched opening 120. In other embodiments, the mask modification method may be used to modify the notched mask 108 into a desired shape different from the former shape 107.

In step C, a first deposition layer 171 is deposited using a first flux 130 at a first polar angle (θ₁). The first flux 130 is directed at the substrate 10 in a manner that allows material to be deposited on one side of the notched opening 120 and without depositing on sidewalls of the target layer 104.

Step D illustrates the substrate 10 after depositing the first deposition layer 171, and illustrates the deposition of a second deposition layer 172 using a second flux 140 at a second polar angle (θ₂). In one or more embodiments, the second polar angle differs from the first polar angle, allowing for more precise shaping of the restoration layers. For example, in various embodiments, the second polar angle is smaller than the first polar angle, and each subsequent polar angle used to deposit a layer to restore/modify the notched mask 108 is smaller than the previous polar angle used. In other embodiments, the second polar angle is larger than the first polar angle, and each subsequent polar angle used to deposit a layer to restore/modify the notched mask 108 is larger than the previous polar angle used. In various embodiments, thicknesses of the various deposition layers may be controlled by exposing the notched mask 108 to the various fluxes for different timeframes using a corresponding plurality of processing times.

In step E, a third deposition layer 173 is deposited using a third flux 150 at a third polar angle (θ₃). This layer further contributes to the restoration of the former shape 107. And step F illustrates the deposition of a fourth deposition layer 174 using a fourth flux 160 at a fourth polar angle (θ₄). In various embodiments, this final deposition step completes the formation of the first restoration layers 170 on one side of the notched mask 108.

Each of the various polar angles used to deposit the various deposition layers (171, 172, 173, and 174) may be chosen such that the amount of layers used to restore/modify the notched mask 108 is minimized. Additionally, the various polar angles may be determined or chosen such that material is not deposited on sidewalls of the target layer 104. As a result, in various embodiments, parameters of the notched mask 108 (such as critical dimension, thickness, and notch width) may be measured and subsequently used to determine the various polar angles used to deposit the various deposition layers to restore/modify the notched mask 108. The selection of the polar angles is described further using FIGS. 4A and 5A below.

Step G illustrates the result after forming the first restoration layers 170, which restore one side of the notched mask 108 to its former shape 107. In an embodiment, this restored shape allows for improved control over subsequent etching processes, potentially reducing issues such as bowing or other undesired feature formations. Additionally, the notched mask 108 comprising the first restoration layers 170 now has a modified notched opening 125.

In various embodiments, the mask layer 106 and the notched mask 108 may comprise the same material which may be an amorphous carbon layer (ACL), some form of metal hardmask, or other suitable mask material conventionally used to form high-aspect-ratio features. In various embodiments, the target layer 104 may be a dielectric layer comprising conventional materials used in dielectric layers. In other embodiments, the target layer 104 may comprise multiple alternating first and second dielectric layers used to form a memory stack. In various embodiments, the substrate 10 may be any conventional wafer, or semiconducting substrate conventionally used in semiconductor fabrication. And in various embodiments, the underlying layer 102 may comprise an integrated circuit previously formed, or may be a base of the substrate 10.

The first restoration layers 170 may comprise the same material in various embodiments, and different materials in other embodiments. Additionally, the various deposited layers of the first restoration layers 170 may comprise different thickness, which may be achieved by depositing for different timeframes at the various polar angles. Additionally, though only four polar angles are illustrated in FIG. 1, other embodiments may use more or less than four polar angles to deposit more or less deposition layers to form the first restoration layers 170.

The various fluxes used to deposit the first restoration layers 170 may be produced by a suitable processing tool for depositing the first restoration layers 170. For example, the processing tool may be a gas cluster beam (GCB) tool configured to emit a beam comprising gas clusters in an embodiment. In other embodiments, the processing tool may be an oblique angle deposition (OAD) tool, or a physical vapor deposition (PVD) tool (to deposit gas phase material). Further, the various fluxes may be used to deposit the first restoration layers 170 comprising the same material as the notched mask 108. For example, in an embodiment where the notched mask 108 comprises an amorphous carbon layer (ACL), the fluxes may be used to deposit carbon to form the various deposition layers, which also comprise carbon.

The mask modification method illustrated in FIG. 1 provides enhanced control over the mask profile during etching processes. In various embodiments, this method allows for the correction of mask notching without significantly altering other process parameters, potentially leading to improved feature formation in high aspect ratio structures and preventing bowing. The mask modification method may also be used in embodiments where the mask layer 106 has not yet been processed, where the shape of the mask layer 106 may be reshaped as desired.

Steps B-E of FIG. 1 are performed while maintaining the substrate 10 at a first azimuthal angle (φ₁). And as a result, only a single sidewall is exposed to the various fluxes to deposit the first restoration layers 170. Depending on the features being formed, the substrate 10 may be rotated about the Z-axis to a new azimuthal angle, and the steps B-E may be performed again to deposit additional restoration layers on a different sidewall of the notched mask 108. For example, in an embodiment where high-aspect ratio contacts (HARCs) are being formed, steps B-E may be performed at four different azimuthal angles to square (repair) the notched mask 108. As another example, in an embodiment where high-aspect-ratio trenches (HARTs) are being formed, steps B-E may be performed at two different azimuthal angles, such as at 0˚ and 180˚, to reshape both sides of a trench feature pattern in the notched mask 108.

FIG. 2 illustrates a continuation of the mask modification method depicted in FIG. 1. In this figure, the process is applied to a second sidewall of the notched mask 108 to form a restored mask 210 by processing at a second azimuthal angle (φ₂). The figure illustrates a cross-sectional view of the substrate 10 through various steps of this restoration process.

Step A of FIG. 2 begins where FIG. 1 ended, showing the substrate 10 with the first restoration layers 170 applied to one side of the notched mask 108, and the substrate now rotated about the Z-axis to the second azimuthal angle (φ₂). The underlying layer 102, target layer 104, and partially etched feature are visible in this initial state.

In step B, a first deposition layer 271 of the second restoration layers 270 is deposited using the first flux 130 at the first polar angle (θ₁). This first flux 130 is directed at the substrate 10 in a manner that allows material to be deposited on the opposite side of the modified notched opening 125 compared to the first restoration layers 170. The embodiment illustrated in FIG. 2 is for a substrate 10 comprising symmetric features. In other embodiments, a different flux at a different polar angle may be used, such as when the features being formed are not symmetric. Additionally, the reshaping or modifying of the notched mask 108 may be performed at various polar angles as desired to form a modified patterned mask in a different desired shape for processing.

Step C depicts the addition of a second deposition layer 272 to the second restoration layers 270. In various embodiments, this layer is deposited using the second flux 140 at the second polar angle (θ₂), differing from the first polar angle (θ₁) to achieve the desired shape restoration. In step D, a third deposition layer 273 is applied to further build up the second restoration layers 270. This layer is deposited using the third flux 150 at the third polar angle (θ₃), contributing to the progressive restoration of the former shape 107.

Step E shows the deposition of a fourth deposition layer 274, completing the formation of the second restoration layers 270. In one or more embodiments, this final layer is deposited using the fourth flux 160 at the fourth polar angle (θ₄), fine-tuning the mask profile. And step F illustrates the final result of the mask modification method. The notched mask 108 has been transformed into a restored mask 210, with both sides of the original notched opening 120 now reformed into a restored opening 126. In an embodiment, this restored opening 126 more closely resembles the shape of the original opening 110 from FIG. 1, step A.

The restored mask 210 features a profile that is more conducive to subsequent etching processes. In various embodiments, this restored profile allows for improved control over feature formation, potentially reducing issues such as bowing or other undesired effects that can occur during high aspect ratio etching. In other embodiments, the restored mask 210 may be referred to as a restored patterned mask. Further, other embodiments may modify the notched mask 108 to form a modified patterned mask or a reshaped patterned mask. In those embodiments, the restored mask 210 may be a modified patterned mask or a restored patterned mask.

The process illustrated in FIG. 2 complements the steps shown in FIG. 1, demonstrating a comprehensive approach to mask modification. By addressing both sides of the notched mask 108, this method provides a more complete restoration of the mask profile. In one or more embodiments, this bilateral restoration process enhances the uniformity and symmetry of the restored opening 126, which can lead to improved consistency in subsequent etching steps. Other embodiments may perform the same steps illustrated in FIG. 2 at additional azimuthal angles to restore the notched mask 108 at even higher quality. Additionally, other embodiments may use different sets of polar angles for each azimuthal angle, or vice versa. Further, FIG. 2 using the same polar angles and fluxes as FIG. 1 may be for a symmetric feature embodiment. Other embodiments may use different polar angles and different various fluxes to form the second restoration layers 270, such as in embodiments where the feature being formed is not symmetric.

The mask modification method depicted across FIGS. 1 and 2 allows for the correction of mask notching without significantly altering other process parameters, potentially leading to enhanced control over feature dimensions and profiles in high aspect ratio structures. The mask modification method may also be applied to reshape patterned masks in general. For example, the patterning of a patterned mask may be adjusted through the deposition of the various layers at the various polar and azimuthal angles (θ, φ) such that the patterned mask may be reshaped to a desired form. Additionally, the mask modification method may also enable the use of metal hardmasks in high-aspect-ratio etching processes. In other embodiments, after performing the restoration of the notched mask 108, an annealing step may be implemented on the substrate 10 to densify the various restoration layers (170 and 270).

FIGS. 3A-3D illustrate cross-sectional views of the substrate 10 through various steps of a cyclic process alternating between etching, and performing the mask modification method of FIGS. 1-2 until a feature is formed.

FIG. 3A illustrates the state of the substrate 10 after completing the mask modification method described in FIGS. 1 and 2. This figure provides a cross-sectional view of the restored mask structure and the partially etched feature.

The restored mask 210 is the result of the sequential deposition processes detailed in FIGS. 1 and 2. In various embodiments, this restored mask 210 features a profile that closely resembles the original mask shape prior to notching. The restored opening 126 in the mask 210 exhibits a more uniform and symmetrical profile compared to the notched opening seen in earlier stages of the process. Notably, the feature being etched in the target layer 104 is visible beneath the restored opening 126. In an embodiment, this feature has been partially formed during the initial etching process that occurred before the mask modification method was applied.

The first restoration layers 170 and second restoration layers 270, applied in the steps illustrated in FIGS. 1 and 2 respectively, have combined to form the restored mask 210. These layers have effectively compensated for the notching that occurred during the initial etching process, resulting in a mask profile that is more conducive to continued etching.

FIG. 3B illustrates the state of the substrate 10 after additional etching has been performed following the mask modification method described in FIGS. 1 and 2. This figure provides a cross-sectional view of the etched feature and the mask structure after renewed notching has occurred.

In FIG. 3B, the substrate 10 is shown with its underlying layer 102 intact at the base. The target layer 104 has been further etched by a suitable etching process for forming the desired features according to the feature pattern of the restored mask 210. This etched feature, which may be a trench or contact, now extends deeper into the target layer 104, but notching has occurred again revealing the notched mask 108 and forming a notched opening 310. In one or more embodiments, the formation of these new notches is a result of the erosion of the mask material during the extended etching process. Consequently, the etching process may be stopped so that the mask modification method may be performed again to restore the notched mask 108.

The feature being etched in the target layer 104 has progressed significantly compared to its state in FIG. 3A. The depth of the feature has increased, potentially approaching the desired final depth for the intended structure. However, the renewed notching of the mask may start to impact the geometry of the etched feature if the etching process continues without intervention. In various embodiments, the etching process may be any suitable etching process for forming the features in accordance with the feature pattern of the restored mask 210. For example, the etching process may be a conventional plasma-etch, or a reactive ion etch (RIE) process. In other embodiments, a wet etching process may be used.

FIG. 3C illustrates the state of the substrate 10 after reapplying the mask modification method described in FIGS. 1 and 2. This figure provides a cross-sectional view of the substrate 10 comprising the newly restored mask 210 and a second restored opening 326.

In FIG. 3C, the substrate 10 is shown with its underlying layer 102 still intact at the base. The target layer 104 maintains the deep feature that was etched prior to this mask restoration step, as seen in FIG. 3B. This second restored opening 326, which may be a trench or contact, extends significantly into the target layer 104. After reforming the restored mask 210 in FIG. 3C, the etching process may resume until either the feature is formed, or mask notching occurs again at a level which may cause bowing or other fabrication faults.

In an embodiment, the state depicted in FIG. 3C represents a point at which etching could potentially resume with a more favorable mask profile. The second restored mask 210 provides a renewed opportunity for controlled etching, potentially allowing for the achievement of higher aspect ratios or more precise feature shapes.

FIG. 3D illustrates the final state of the substrate 10 after completing the etching process to form a feature 330 that extends through the target layer 104 and reveals the underlying layer 102. This figure provides a cross-sectional view of the completed feature and the remaining mask structure.

In FIG. 3D, the substrate 10 is shown with its underlying layer 102 now exposed at the bottom of the newly formed feature 330. The target layer 104, which was the primary subject of the etching process, has been completely penetrated in the area defined by the mask opening. And as a result of cyclically etching and restoring a notched mask using the mask modification method, bowing of the feature 330 was prevented.

The feature 330, which may be a high aspect ratio trench or contact, extends from the top surface of the target layer 104 down to the underlying layer 102. In various embodiments, this feature 330 represents the culmination of the iterative etching and mask restoration processes described in the previous figures.

The mask layer, which has undergone multiple cycles of notching and restoration as illustrated in FIGS. 3A through 3C, is still present atop the target layer 104. In one or more embodiments, this remaining mask material, labeled as notched mask 108, may show signs of erosion or notching from the final etching stage. The exact profile of this remaining mask may vary depending on the specific process parameters and the number of etching and restoration cycles performed.

The sidewalls of the feature 330 in the target layer 104 exhibit a relatively straight and uniform profile. In an embodiment, this uniformity is a result of the repeated application of the mask modification method throughout the etching process. The controlled mask profile maintained throughout the etching steps potentially allows for more precise feature formation, minimizing issues such as bowing or other undesired geometries that can occur in high aspect ratio etching.

The exposure of the underlying layer 102 at the bottom of the feature 330 signifies the achievement of the desired etch depth. In one or more embodiments, this endpoint may be detected through various methods, such as optical emission spectroscopy or other in-situ monitoring techniques, allowing for precise control over the final feature depth.

FIG. 3D thus represents the successful completion of a high aspect ratio etching process facilitated by the iterative mask modification method. It showcases how this approach potentially enables the formation of deep, uniform features that might be challenging to achieve with conventional single-step masking techniques. The resulting structure sets the stage for subsequent processing steps, such as filling the feature with conductive or insulating materials, depending on the specific application of the fabricated device.

FIGS. 4A-4B illustrate the coordinate system and deposition process used in the mask restoration method. Together, these figures demonstrate how precise control over the deposition angles enables targeted material deposition for effective mask profile restoration enabling compensation of mask notching that occurs during high-aspect-ratio etching processes.

FIG. 4A illustrates the coordinate system used for the deposition of layers in the mask modification method. This figure provides a three-dimensional representation of the substrate 10 and the directionality of the deposition process using a deposition beam 410. In other embodiments, a deposition flux, or jet, or stream may be used instead of a beam. In various embodiments, the deposition beam 410 may be the first flux 130, the second flux 140, the third flux 150, or the fourth flux 160 described using FIGS. 1-2.

In FIG. 4A, the substrate 10 is shown in relation to a three-dimensional Cartesian coordinate system. The coordinate system is defined with X, Y, and Z axes, where the X-Y plane is parallel to the surface of the substrate 10. In various embodiments, the Z-axis is perpendicular to the substrate surface and represents the direction of substrate thickness. Further, the Z-axis may be a normal direction of the surface of the substrate 10.

The deposition beam 410 represents the source of material for depositing layers according to the mask modification method. In one or more embodiments, this deposition beam 410 may be generated by various deposition techniques such as physical vapor deposition (PVD), oblique angle deposition (OAD), gas cluster beam (GCB) tools, or other suitable methods.

Two angles are illustrated in FIG. 4A to describe the orientation of the deposition beam 410 relative to the substrate 10. The angle φ (phi) represents the azimuthal angle in the X-Y plane. The azimuthal angle is measured from the positive X-axis and describes the rotation of the deposition beam 410 around the Z-axis (or the normal direction of the surface of the substrate 10). Additionally, the angle θ (theta) represents the polar angle measured from the Z-axis. The polar angle describes the tilt of the deposition beam 410 relative to the normal of the substrate surface (the Z-axis).

In an embodiment, these angles φ and θ can be controlled to direct the deposition beam 410 at specific orientations relative to the substrate 10. This directional control enables the targeted deposition of material to compensate for mask notching, or to modify a mask as desired, as described in the previous figures.

The ability to adjust both φ and θ allows for a wide range of deposition angles and directions. In various embodiments, this flexibility enables the precise shaping of the restored mask layers, allowing for effective compensation of mask notching regardless of the specific geometry of the etched features or the orientation of the mask openings on the substrate.

FIG. 4B illustrates the interaction between a deposition flux 420 and the notched opening 120 in the mask layer on the substrate 10. This figure provides a cross-sectional view to demonstrate how the angled deposition contributes to the mask restoration process.

The deposition flux 420 is illustrated approaching the substrate 10 in a direction defined by φ and θ, as established in the coordinate system of FIG. 4A. The angled nature of this flux enables it to contact the side of the notched opening 120, depositing material in a controlled manner. In various embodiments, this targeted deposition enables the gradual buildup of material on the notched surfaces, effectively restoring the original mask profile, or modifying the mask layer of the substrate 10 as desired. By adjusting the angles φ and θ, the deposition can be precisely directed to different areas of the notched opening 120, allowing for the creation of the restoration layers described in previous figures. This process can be repeated with different angle combinations to achieve the desired mask profile restoration.

FIGS. 5A-5B illustrate the substrate 10, and are used to describe how the various deposition angles used in the mask modification method of this disclosure may be determined.

FIG. 5A illustrates the variation in angles of the deposition beams used to restore the mask profile in the notched opening 120 in an embodiment. In other embodiments, the deposition beams may be used to modify the notched opening 120 as desired. This figure provides a cross-sectional view of the substrate 10, showing how different angled beams are employed to deposit the various restoration layers and how various dimensions of the notched mask may be used to determine the various deposition angles for the mask modification method.

The substrate 10 comprises the underlying layer 102, the target layer 104, and the notched mask 108 with a notched opening 120. The former shape 107 of the mask layer (prior to an etch process forming notches) is indicated by the dashed box. In various embodiments, the former shape 107 may represent the profile that the restoration process aims to recreate.

Multiple angled beams are depicted, each approaching the notched opening 120 at a different angle. These beams are labeled as a first angled beam 510, a second angled beam 520, a third angled beam 530, and a fourth angled beam 540. In various embodiments, each of these beams corresponds to a different deposition step in the mask modification method. For example, in an embodiment, the first angled beam 510 may be directed into the notched opening 120 at a first polar angle (θ₁). Similarly, the second angled beam 520 may be directed into the notched opening 120 at a second polar angle (θ₂), and the same may be true for the third angled beam 530 at a third polar angle (θ₃) and the fourth angled beam 540 at a fourth polar angle (θ₄).

FIG. 5A illustrates how the angles of these beams are varied to target specific areas of the notched opening 120 to deposit various layers in accordance with the mask modification method of this disclosure. The first angled beam 510 is shown with the steepest angle, depositing material over the entire sidewall of the notch. Each subsequent beam (520, 530, and 540) has a progressively shallower angle, allowing for deposition higher up the notched surface.

Various dimensions of the notched mask 108 are illustrated in the FIG. 5A. A height (h) represents the vertical distance from the bottom of the notched mask 108 to the top of the notch. A width (a) represents the horizontal width of the notches of the notched mask 108. And a width (b) represents the horizontal width (or critical dimension) of the notched opening 120. The width (b) may be the smallest distance between adjacent notches in other embodiments.

In one or more embodiments, these dimensions may be used to determine the specific angles of the beams (510, 520, 530, and 540) to deposit the various layers to restore the notched mask 108 to the former shape 107. The variation in beam angles allows for precise control over the deposition process, enabling the gradual buildup of material to restore the notched mask to the former shape 107.

In various embodiments, the angles may be determined such that the notches shadow the beams to prevent the beams from depositing material on sidewalls of the target material 104. In one or more embodiments, a light detector may be used to measure and determine a topological map of the notched mask 108, and the topological map may be used to determine the dimensions of the notches, and subsequently determine the number of layers to deposit over the notched mask 108 with the corresponding polar angles. In those embodiments, the light detector may be used in combination with optical critical dimension (OCD) metrology to determine the topological map of the notched mask 108. For example, the light detector may be a suitable light detector for performing OCD metrology. In various embodiments, the light detector may be a charge-coupled device (CCD) detector, a complementary metal-oxide-semiconductor (CMOS) detector, a photodiode array, photomultiplier tubes (PMTs), avalanche photodiodes (APDs), or combinations of these.

In other embodiments, the light detector may be used with a critical dimension small angle x-ray scattering (CD-SAXS) technique to determine the topological map of the notched mask 108. And as an example, the light detector may be a suitable detector for performing CD-SAXS.

FIG. 5B illustrates a cross-sectional view of a single notch in the notched mask 108 of the substrate 10 where the mask notch has been repaired using the mask modification method described in this disclosure to form the restored mask 210. As illustrated in FIG. 5B, the notch has been repaired such that the former shape of the mask has been restored by depositing various layers using angled deposition beams, or fluxes, or jets, or streams.

The restored mask 210 structure comprises multiple deposited layers. The left side comprises the first restoration layers 170, comprising the various deposition layers 171, 172, 173, and 174. Mirroring this structure, the right side comprises the second restoration layers 270, comprising the various deposition layers 271, 272, 273, and 274. These layers correspond to deposition steps using different angles, as illustrated in the previous figures and described using FIGS. 1-2.

The combination of these restoration layers (170 and 270) forms the restored mask 210, which closely approximates the profile of the original mask before notching occurred. The restored mask 210 exhibits a more uniform and symmetrical profile compared to the notched mask 108 that would have been present before the restoration process. Consequently, stopping an etch process and performing the intermediate repair of the notched mask 108 using the method of this disclosure may prevent bowing of high-aspect-ratio features being etched. In various embodiments, this restored profile allows for improved control over subsequent etching steps, demonstrating how the mask modification method can effectively rebuild the mask profile for high-aspect-ratio etching processes.

In various embodiments, the various deposition layers (171, 172, 173, and 174) may be deposited for a corresponding timeframe that is different from the timeframes of the other deposition layers. For example, the first deposition layer 171 may be exposed to the first angled beam 510 for a first timeframe that is longer than a second timeframe used to deposit the second deposition layer 172. In that example, the first deposition layer 171 may consequently be thicker than the second deposition layer 172 due to the larger first timeframe of the first angled beam 510 at the first polar angle.

An embodiment processing system 60 is described below using FIG. 6. In various embodiments, the processing system 60 may be a gas cluster beam (GCB) system, or an ion implantation system. The processing system 60 may be used to implement the mask modification method of this disclosure which uses angled beam exposure to modify (or restore) a notched mask of a substrate 642 after performing an etch step. In the embodiment illustrated in FIG. 6, an ion beam or a gas cluster beam may be used to modify a notched mask of the substrate 642.

The processing system 60 in FIG. 6 comprises a scanning chamber 600 that houses a scanning mechanism comprising actuators, moving parts, hinges, and a substrate holder 644, collectively referred to as a scanner 645; a processing chamber 608 where the substrate 642 (loaded onto the scanner 645) may intersect a beam 613 emitted over an area 655 of the substrate 642 by a processing nozzle 612 coupled with a processing tool 695 for processing the substrate 642; and a rotatable feedthrough 630 between the scanning chamber 600 and the processing chamber 608 through which a moving part of the scanner 645 can access and move the substrate 642 within the processing chamber 608. The combined continuous motion of the movable parts of the scanner 645 and discrete rotary motion of the scanning chamber 600 using the rotatable feedthrough 630 may provide the desired movements or polar angles of the substrate 642 through the beam 613 to complete the mask modification of the substrate 642 in accordance with embodiment methods of this disclosure.

The processing system 60 is capable of implementing both blanket exposure (using a flux of material instead of the beam 613) and scanning methods. For blanket exposure, the processing nozzle 612 may be designed to emit a wide beam covering the entire top surface of the substrate 642. For scanning applications, the scanner 645, in conjunction with the rotatable feedthrough 630, can move the substrate 642 relative to a more focused (or collimated) beam from the processing nozzle 612.

Though FIG. 6 illustrates the processing system 60 comprising a beam forming apparatus (such as a gas cluster beam or ion implantation system), other embodiments may use a plasma system to emit a plasma jet over the substrate 642 to modify the notched mask and thereby alleviate bowing of etched features. Accordingly, in this embodiment, the scanning chamber 600, the scanner 645, and the rotatable feedthrough 630 are together referred to as a scanning apparatus 650. The full range of motion of the scanning apparatus 650 and of the substrate 642 relative to the beam 613 impinging on its surface is described in further detail below.

In an embodiment where the beam 613 comprises a plasma jet, the plasma jet may comprise plasma effluent, ionized species, neutral or non-ionized species, radical or dissociated species, metastable species, or combinations thereof. The plasma jet can be tailored to emit one or more species substantially exclusive of others, i.e., emit neutral species while substantially omitting ionized species. The plasma jet can be formed using plasma generated remotely or in-situ with the processing nozzle 612. In the latter, plasma-generating elements can be coupled to the conduit flowing gas(es) through the processing nozzle 612.

The processing system 60 further comprises a load lock 680, where wafers for processing may be placed, and a wafer transfer chamber 670. The substrate 642 may be transported from the load lock 680 to the substrate holder 644 of the scanner 645 using, for example, an (r, θ, z) robotic arm located in the wafer transfer chamber 670. A wafer transfer window in the processing chamber 608 may be used to transfer the substrate 642 from the wafer transfer chamber 670 to the substrate holder 644.

The processing system further comprises a controller 601 to control the rotary drives of the scanning apparatus 650, and to control the various gas inlets and accelerators of a gas cluster beam generator or an ion implantation generator to form the beam 613 with the desired parameters for modifying the notched mask of the substrate 642. Further, the controller 601 may be coupled with the processing tool 695 to control various aspects of the processing tool to form the beam 613 emitted from the processing nozzle 612 over the substrate 642. In various embodiments, the processing tool 695 may be a gas cluster beam (GCB) tool, an ion implantation tool, or a plasma tool (such as a plasma jet). The controller 601 may be used to implement the mask modification method of this disclosure by executing instructions stored in a memory 681. The memory 681 may be any suitable storage device capable of storing the instructions to be executed by the controller 601.

As illustrated in FIG. 6, the processing system 60 may comprise a vacuum system 690 connected to the scanning chamber 600, the processing chamber 608, the wafer transfer chamber 670, and the load lock 680. The connection between the scanning chamber 600 and the processing chamber 608 may be controlled by a rotary seal in the rotatable feedthrough 630, and the connections between the load lock 680, the wafer transfer chamber 670, and the processing chamber 608 may be controlled by two gate valves 660, as indicated schematically in FIG. 6.

To deposit the various layers to compensate the notched mask of the substrate 642, the processing system 60 uses the scanning apparatus 650. In one embodiment, two rotary drives (a first rotary drive 602 and a second rotary drive 604) are used as the primary actuators of the scanner 645. Synchronous angular displacements of the first and the second rotary drives 602 and 604 may be accurately computed in accordance with a desired planar trajectory of the center of the substrate holder 644, and subsequently used by a controller 601 to generate the computed synchronized rotational motions with high precision using, for example, electronically controllable motors. Generally, the choices of drives, couplings and bearings are made to reduce backlash. The synchronized pair of rotations actuated by the first and the second rotary drives 602 and 604 is converted to a target scan trajectory of the center of the substrate holder 644 via various other moving parts of the scanner 645. The trajectory of the substrate holder 644, hence, also the trajectory of the substrate 642 loaded onto the substrate holder 644, is substantially coplanar with (or parallel to) the processing surface of the substrate 642.

In one embodiment, the rotational motion of the first and the second rotary drives 602 and 604 may be translated to a planar motion along the plane of the surface of substrate 642 using a bar-and-hinge system comprising five bar links (a first bar link 621, a second bar link 623, a third bar link 624, a fourth bar link 625, and a belted fifth bar link 622), and three hinges (a first hinge 605, a second hinge 606, and a third hinge 607) about which the bar links can rotate.

The belted fifth bar link 622 comprises a bar link 626 and a motorized belt-and-pulley system 627 in the bar link 626. The motorized belt-and-pulley system 627 may be used to orient the substrate 642 by rotating the planar surface of the substrate holder 644 along with the substrate 642. In various other embodiments, the mechanism used to rotate the substrate holder 644 may be implemented differently.

In one embodiment, the substrate 642 is placed on the substrate holder 644 such that the centers of the substrate holder 644 and substrate 642 are substantially coincident. The common center point is defined as the origin of a three-dimensional rectangular coordinate system (X, Y, Z), as illustrated in FIG. 4A. The X-Y plane is the plane containing the planar trajectory derived from the synchronized rotations of the first and the second rotary drives 602 and 604, as described above. As illustrated in FIG. 4A, the X-Y plane is virtually the same (or coplanar) as the surface of the substrate 642 (or the substrate holder 644). Accordingly, the Z-axis (not visible in the two-dimensional view in FIG. 6) points in a direction normal to this surface. The direction of the Y-axis could be selected along any particular orientation in the plane of the wafer. For specificity, in the figures in this disclosure, the Y-axis is selected to pass through a wafer notch. It is also customary to indicate a particular orientation of a crystalline semiconductor substrate by a physical mark on the wafer, such as the notch near the circumference of the circular substrate 642 in FIG. 6.

The angle formed by the Z-axis (or any other line normal to the X-Y plane) and the processing beam (e.g., the beam 613) is referred to as the polar angle, θ. As an example, the polar angle (θ) may be either the first angle (θ₁) of the first flux 130, the second angle (θ₂) of the second flux 140, the third angle (θ₃) of the third flux 150, or the fourth angle (θ₄) of the fourth flux 160 in FIGS. 1-2. As described above, the polar angle, may be configured such that the mask modification method deposits as many layers as desired to repair the notched mask of the substrate. For example, some embodiments may use as many as 10 polar angles to deposit 10 layers to repair the notched mask.

In an embodiment, one side of the rotatable feedthrough 630 is attached rigidly (e.g., bolted) on to a wall of the scanning chamber 600. The opposite side may be placed on rotary bearings attached to an adjacent wall of the processing chamber 608, thereby allowing the scanning chamber 600 to be rotated about an axis passing through the center of the rotatable feedthrough 630 and normal to the wall of the processing chamber 608 to which the rotary part of the rotatable feedthrough 630 is attached. In one embodiment, the polar angle, θ, may be adjusted by rotating the scanning chamber 600 and scanner 645 using the rotatable feedthrough 630.

Still referring to FIG. 6, at any fixed polar angle, θ, the substrate 642 may be rotated in-plane through an azimuthal angle φ, without altering polar angle θ. Generally, zero azimuthal angle (φ = 0°) is defined to be the orientation of the substrate 642 when the notch is downwards and when the substrate 642 is held vertically (θ = 0°) perpendicular to a horizontal beam 613. Since the Y-axis is defined as coincident with the diameter which passes through the notch, the azimuthal angle, φ, is the angular position of the Y-axis relative to the Y-axis at φ = 0°. Accordingly, the azimuthal angle, φ, may be defined to be the angle formed between the X-axis and a reference axis perpendicular to the planar face of the rotatable feedthrough 630. In one embodiment, φ may be set to any value in the range 0° ≤ φ ≤ 360°, where, by convention, azimuthal angle φ is considered to be increasing with counterclockwise rotation and decreasing with clockwise rotation.

Here, the Y-axis has been defined by the position of the notch, so altering the azimuthal angle from 0° to φ is equivalent to rotating the X-Y axes about the Z-axis by an azimuthal angle φ. The angles θ and φ are analogous to the polar angle and azimuthal angle, respectively, of a spherical coordinate system (such as described using FIG. 4A). Consider a substrate 642 positioned with a polar angle, θ, and an azimuthal angle, φ, being scanned through the beam 613 by the scanner 645. Then θ is the angle formed by the Z-axis and the beam 613, and φ is the angle formed by the Y-axis and an orthogonal projection of the beam 613 on the X-Y plane.

In this embodiment, the substrate 642 may be loaded onto the substrate holder 644 at a particular wafer orientation (e.g., at φ = 0°), and subsequently rotated about the Z-axis by a specified azimuthal angle, φ after depositing a layer at a polar angle, θ. The loaded substrate 642 and the substrate holder 644 may be rotated together about an axis passing perpendicularly through the face of the rotatable feedthrough 630 by a polar angle, θ, before moving the substrate through the beam 613. The polar angle θ of the substrate 642 relative to the beam 613 alters the angle at which the beam strikes the substrate 642 and this may be used to deposit the various layers to repair a notched mask in accordance with the mask modification method of this disclosure. As another example, in an embodiment, the second deposition of various layers at various polar angles, θ, to the beam 613 at a different azimuthal angle, φ, to repair the notched mask of the substrate 642 may be performed by rotating the azimuthal angle 180˚ and subsequently depositing the various layers at the various polar angles, such as described using FIG. 2.

For process steps where it is desired that the surface be exposed to the processing beam at several discrete combinations of polar angle θ and azimuthal angle φ, the process recipe may be constructed to pass the substrate through several scans with the tilt and azimuthal angles (θ, φ) combination being altered between successive scans. The azimuthal angle may be adjusted without removing the substrate 642 from the substrate holder 644 using, for example, an electronically controlled motorized belt-and-pulley system 627. The polar angle, or the azimuthal angle, or both may be dynamically controlled while the substrate 642 is being scanned through the beam 613.

In various embodiments, the processing system 60 comprises a light detector 697, which may be used to collect light from the substrate 642 to determine the various azimuthal and polar angles to be used to modify a mask of the substrate 642. For example, the light detector 697 may be coupled to the controller 601, and the controller 601 may use optical critical dimension (OCD) metrology to determine a topological map which may be used to determine the various azimuthal and polar angles to modify a mask of the substrate 642 as desired. In other embodiments, the controller 601 may use the light detector 697 for critical dimension small angle x-ray scattering (CD-SAXS) techniques to determine the various azimuthal and polar angles to modify a mask of the substrate 642 as desired. The light detector 697 may be coupled to the processing chamber 608 through windows in other embodiments. The light detector 697 may be any suitable device for detecting light from the substrate 642, such as a charge-coupled device (CCD) detector, a complementary metal-oxide-semiconductor (CMOS) detector, a photodiode array, photomultiplier tubes (PMTs), avalanche photodiodes (APDs), or combinations of these.

FIGS. 7-8 are flowcharts illustrating example mask modification methods in accordance with embodiments of the disclosure. The methods of FIGS. 7-8 may be combined with other methods and performed using the systems and apparatuses as described herein. For example, the methods of FIGS. 7-8 may be implemented in the processing system 60 of FIG. 6. Although shown in a logical order, the arrangement and numbering of the steps of FIGS. 7-8 are not intended to be limiting.

Referring to FIG. 7, step 710 of a method 700 for mask modification receives a substrate on a substrate holder. The substrate comprises a patterned mask disposed over a patterned underlying layer, the patterned mask comprising notches. After, the method 700 has a plurality of polar angles and a plurality of processing times in step 720. Each of the plurality of polar angles have an associated one of the plurality of processing times.

Still referring to FIG. 7, the method 700 processes the substrate with a cyclic process for each of the plurality of polar angles in step 730. One cycle of the cyclic process comprises performing steps 732, 734, and 736.

In step 732, the cyclic process of the method 700 selects a polar angle (θᵢ) from the plurality of polar angles, the selected polar angle being higher than any polar angle from the plurality of polar angles previously selected in the cyclic process and lower than any polar angle from the plurality of polar angles remaining to be selected. In step 734, the cyclic process of the method 700 tilts a processing tool such that a beam emitted from the processing tool strikes the substrate at the selected polar angle (θᵢ). And in step 736, the cyclic process of the method 700 emits the beam at the selected polar angle (θᵢ) for an i^{th} timeframe (tᵢ) corresponding to the selected polar angle (θᵢ) to deposit an i^{th} layer over the notches. In various embodiments, the i layers may be the first restoration layers 170 of FIG. 1 or the second restoration layers 270 of FIG. 2. Further, each i^{th} layer may correspond to a respective deposition layer (171, 172, 173, 174, 271, 271, 273, or 274) of FIGS. 1or2.

Now referring to FIG. 8, step 810 of a method 800 of processing a substrate receives the substrate on a substrate holder. The substrate comprises an underlying layer and a patterned mask, the patterned mask comprises a feature pattern. For example, the substrate may be the substrate 10 of FIGS. 1-2, the underlying layer may be the underlying layer 102 or the target material 104 of FIGS. 1-2, and the patterned mask may be the notched mask 108 of FIGS. 1-2. Further, the patterned mask may comprise notches formed from a previous etch step.

After, in step 820, the method 800 determines a topological map of the patterned mask by scanning the substrate. In various embodiments, this may be performed by scanning the substrate with a light beam, by performing OCD metrology using a light detector (such as the light detector 697 illustrated in FIG. 6), or by performing CD-SAXS techniques using the light detector, or some other form of imaging or measurement apparatus conventionally used to determine surface topology of a substrate, and capable of measuring the feature pattern.

In step 830, the method 800 deposits i layers over the patterned mask to reshape the patterned mask. Each of the i layers may be deposited by emitting a beam (or a flux, or jet, or stream) from a processing tool over the substrate at a corresponding i^{th} polar angle (θᵢ) for a corresponding i^{th} timeframe (tᵢ), where i is a positive integer between 1 and 100.

Example embodiments of the invention are described below. Other embodiments can also be understood from the entirety of the specification as well as the claims filed herein.

Example 1. A method for processing a substrate includes receiving the substrate on a substrate holder, the substrate including a patterned mask disposed over a patterned underlying layer, the patterned mask including notches. The method further includes having a plurality of polar angles and a plurality of processing times, each of the plurality of polar angles having an associated one of the plurality of processing times, and processing the substrate with a cyclic process for each of the plurality of polar angles. Each cycle of the cyclic process includes selecting a polar angle (θᵢ) from the plurality of polar angles, the selected polar angle being higher than any polar angle from the plurality of polar angles previously selected in the cyclic process for processing the substrate and lower than any polar angle from the plurality of polar angles remaining to be selected in the cyclic process for processing the substrate. Each cycle of the cyclic process further includes tilting a processing tool such that a beam emitted from the processing tool strikes the substrate at the selected polar angle (θᵢ), and emitting the beam at the selected polar angle (θᵢ) for an i^{th} timeframe (tᵢ) corresponding to the selected polar angle (θᵢ) to deposit an i^{th} layer over the notches.

Example 2. The method of example 1, further includes having a plurality of azimuthal angles, the plurality of azimuthal angles including j azimuthal angles (φⱼ), where j is a positive integer between 2 and 100. And the method further includes performing a second cyclic process for each of the plurality of azimuthal angles to form a restored patterned mask. One cycle of the second cyclic process includes selecting an azimuthal angle (φⱼ) from the plurality of azimuthal angles, the selected azimuthal angle being higher than any azimuthal angle from the plurality of azimuthal angles previously selected in the second cyclic process and lower than any azimuthal angle from the plurality of azimuthal angles remaining to be selected in the second cyclic process. One cycle of the second cyclic process further includes rotating the substrate about a polar axis of the substrate to the selected azimuthal angle (φⱼ), and processing the substrate with the cyclic process for each of the plurality of polar angles.

Example 3. The method of one of examples 1 or 2, further includes annealing the substrate to densify the i layers over the notches and form the restored patterned mask.

Example 4. The method of one of examples 1 to 3, further includes etching the substrate to transfer a feature pattern to the patterned underlying layer according to the restored patterned mask.

Example 5. The method of one of examples 1 to 4, further includes, in response to forming new notches in the restored patterned mask before completing the etching, stopping the etching and performing the cyclic process and the second cyclic process to form a second restored patterned mask, and resuming the etching of the substrate to transfer the feature pattern to the patterned underlying layer according to the second restored patterned mask.

Example 6. The method of one of examples 1 to 5, where the feature pattern includes high aspect ratio contacts (HARCs), the patterned mask is a patterned amorphous carbon layer (ACL), the i layers deposited over the notches include carbon, and j is 4.

Example 7. The method of one of examples 1 to 6, where the feature pattern includes high aspect ratio trenches (HARTs), the patterned mask is a patterned amorphous carbon layer (ACL), the i layers deposited over the notches include carbon, and j is 2.

Example 8. The method of one of examples 1 to 7, where each of the i^{th} timeframes (tᵢ) are different such that each i^{th} layer deposited over the notches has a different thickness.

Example 9. The method of one of examples 1 to 8, where the restored patterned mask includes the feature pattern of an original patterned mask.

Example 10. The method of one of examples 1 to 9, where the i layers of the restored patterned mask square a shape of openings in the patterned mask to restore the feature pattern.

Example 11. The method of one of examples 1 to 10, where the processing tool includes a gas cluster beam (GCB) tool and the beam includes gas clusters, or the processing tool includes a physical vapor deposition (PVD) tool and the beam includes a flux of gas phase material, or where the processing tool includes an oblique angle deposition (OAD) tool.

Example 12. The method of one of examples 1 to 11, where the emitting of the cyclic process uses a scanner to scan the beam over the substrate.

Example 13. A method for shaping a patterned mask on a substrate includes receiving the substrate on a substrate holder, the substrate including the patterned mask disposed over an underlying layer, the patterned mask including a feature pattern. The method further includes determining a topological map of the patterned mask using a light detector, and depositing i layers over the patterned mask to reshape the patterned mask, each of the i layers deposited by a processing tool directed over the substrate at a corresponding i^{th} polar angle (θᵢ) for a corresponding i^{th} timeframe (tᵢ), where i is a positive integer between 1 and 100 determined using the topological map of the patterned mask and a desired shape for the feature pattern.

Example 14. The method of example 13, further includes annealing the substrate to densify the i layers and form a modified patterned mask including a reshaped feature pattern.

Example 15. The method of one of examples 13 or 14, where the processing tool includes a gas cluster beam (GCB) tool emitting a beam including gas clusters, or the processing tool includes a physical vapor deposition (PVD) tool emitting a beam including a flux of gas phase material, or where the processing tool includes an oblique angle deposition (OAD) tool, or where the processing tool produces either a beam, a jet, or a flux to deposit the i layers.

Example 16. The method of one of examples 13 to 15, further includes rotating the substrate about a center of the substrate to an azimuthal angle, and depositing an additional i layers over the patterned mask to further reshape the patterned mask.

Example 17. A system for processing a substrate includes a substrate holder disposed in a processing chamber, a processing tool, a light detector, and a controller coupled to the substrate holder, the processing tool, the light detector, and a memory storing instructions to be executed by the controller. The instructions, when executed, cause the controller to receive the substrate on the substrate holder, the substrate including a patterned mask disposed over an underlying layer, the patterned mask including a feature pattern, and determine a topological map of the patterned mask using the light detector. And the instructions, when executed further, cause the controller to deposit i layers over the patterned mask to reshape the patterned mask and form a modified patterned mask including a reshaped feature pattern, each of the i layers deposited by the processing tool directed over the substrate at a corresponding i^{th} polar angle (θᵢ) for a corresponding i^{th} timeframe (tᵢ), where i is a positive integer between 1 and 100 determined using the topological map of the patterned mask and a desired shape for the feature pattern.

Example 18. The system of example 17, where the processing tool includes a gas cluster beam (GCB) tool and deposits using a beam including gas clusters.

Example 19. The system of one of examples 17 or 18, where the processing tool includes a physical vapor deposition (PVD) tool and deposits using a flux including gas phase material, or where the processing tool includes an oblique angle deposition (OAD) tool.

Example 20. The system of one of examples 17 to 19, further including a scanner configured to scan the substrate through a beam from the processing tool during the depositing.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for processing a substrate, the method comprising:
receiving the substrate on a substrate holder, the substrate comprising a patterned mask disposed over a patterned underlying layer, the patterned mask comprising notches;
having a plurality of polar angles and a plurality of processing times, each of the plurality of polar angles having an associated one of the plurality of processing times; and
processing the substrate with a cyclic process for each of the plurality of polar angles, each cycle of the cyclic process comprising:
selecting a polar angle (θᵢ) from the plurality of polar angles, the selected polar angle being higher than any polar angle from the plurality of polar angles previously selected in the cyclic process for processing the substrate and lower than any polar angle from the plurality of polar angles remaining to be selected in the cyclic process for processing the substrate;
tilting a processing tool such that a beam emitted from the processing tool strikes the substrate at the selected polar angle (θᵢ); and
emitting the beam at the selected polar angle (θᵢ) for an i^{th} timeframe (tᵢ) corresponding to the selected polar angle (θᵢ) to deposit an i^{th} layer over the notches.

2. The method of claim 1, further comprising:
having a plurality of azimuthal angles, the plurality of azimuthal angles comprising j azimuthal angles (φⱼ), wherein j is a positive integer between 2-100.; and
performing a second cyclic process for each of the plurality of azimuthal angles to form a restored patterned mask, one cycle of the second cyclic process comprising:
selecting an azimuthal angle (φⱼ) from the plurality of azimuthal angles, the selected azimuthal angle being higher than any azimuthal angle from the plurality of azimuthal angles previously selected in the second cyclic process and lower than any azimuthal angle from the plurality of azimuthal angles remaining to be selected in the second cyclic process;
rotating the substrate about a polar axis of the substrate to the selected azimuthal angle (φⱼ); and
processing the substrate with the cyclic process for each of the plurality of polar angles.

3. The method of claim 2, further comprising annealing the substrate to densify the i layers over the notches and form the restored patterned mask.

4. The method of claim 2, further comprising etching the substrate to transfer a feature pattern to the patterned underlying layer according to the restored patterned mask.

5. The method of claim 4, further comprising:
in response to forming new notches in the restored patterned mask before completing the etching, stopping the etching and performing the cyclic process and the second cyclic process to form a second restored patterned mask; and
resuming the etching of the substrate to transfer the feature pattern to the patterned underlying layer according to the second restored patterned mask.

6. The method of claim 4, wherein the feature pattern comprises high aspect ratio contacts (HARCs), the patterned mask is a patterned amorphous carbon layer (ACL), the i layers deposited over the notches comprise carbon, and j is 4.

7. The method of claim 4, wherein the feature pattern comprises high aspect ratio trenches (HARTs), the patterned mask is a patterned amorphous carbon layer (ACL), the i layers deposited over the notches comprise carbon, and j is 2.

8. The method of claim 4, wherein each of the i^{th} timeframes (tᵢ) are different such that each i^{th} layer deposited over the notches has a different thickness.

9. The method of claim 4, wherein the restored patterned mask comprises the feature pattern of an original patterned mask.

10. The method of claim 4, wherein the i layers of the restored patterned mask square a shape of openings in the patterned mask to restore the feature pattern.

11. The method of claim 4, wherein the processing tool comprises a gas cluster beam (GCB) tool and the beam comprises gas clusters, or the processing tool comprises a physical vapor deposition (PVD) tool and the beam comprises a flux of gas phase material, or wherein the processing tool comprises an oblique angle deposition (OAD) tool.

12. The method of claim 4, wherein the emitting of the cyclic process uses a scanner to scan the beam over the substrate.

13. A method for shaping a patterned mask on a substrate, the method comprising:
receiving the substrate on a substrate holder, the substrate comprising the patterned mask disposed over an underlying layer, the patterned mask comprising a feature pattern;
determining a topological map of the patterned mask using a light detector; and
depositing i layers over the patterned mask to reshape the patterned mask, each of the i layers deposited by a processing tool directed over the substrate at a corresponding i^{th} polar angle (θᵢ) for a corresponding i^{th} timeframe (tᵢ), wherein i is a positive integer between 1-100. determined using the topological map of the patterned mask and a desired shape for the feature pattern.

14. The method of claim 13, further comprising annealing the substrate to densify the i layers and form a modified patterned mask comprising a reshaped feature pattern.

15. The method of claim 13, wherein the processing tool comprises a gas cluster beam (GCB) tool emitting a beam comprising gas clusters, or the processing tool comprises a physical vapor deposition (PVD) tool emitting a beam comprising a flux of gas phase material, or wherein the processing tool comprises an oblique angle deposition (OAD) tool, or wherein the processing tool produces either a beam, a jet, or a flux to deposit the i layers.

16. The method of claim 13, further comprising:
rotating the substrate about a center of the substrate to an azimuthal angle; and
depositing an additional i layers over the patterned mask to further reshape the patterned mask.

17. A system for processing a substrate, the system comprising:
a substrate holder disposed in a processing chamber;
a processing tool;
a light detector; and
a controller coupled to the substrate holder, the processing tool, the light detector, and a memory storing instructions to be executed by the controller, the instructions, when executed, cause the controller to:
receive the substrate on the substrate holder, the substrate comprising a patterned mask disposed over an underlying layer, the patterned mask comprising a feature pattern;
determine a topological map of the patterned mask using the light detector; and
deposit i layers over the patterned mask to reshape the patterned mask and form a modified patterned mask comprising a reshaped feature pattern, each of the i layers deposited by the processing tool directed over the substrate at a corresponding i^{th} polar angle (θᵢ) for a corresponding i^{th} timeframe (tᵢ), wherein i is a positive integer between 1-100. determined using the topological map of the patterned mask and a desired shape for the feature pattern.

18. The system of claim 17, wherein the processing tool comprises a gas cluster beam (GCB) tool and deposits using a beam comprising gas clusters.

19. The system of claim 17, wherein the processing tool comprises a physical vapor deposition (PVD) tool and deposits using a flux comprising gas phase material, or wherein the processing tool comprises an oblique angle deposition (OAD) tool.

20. The system of claim 17, further comprising a scanner configured to scan the substrate through a beam from the processing tool during the depositing.
